(19) United States
(12) Patent Application Publication
(10) Pub. No.: US 2026/0136842 A1
(43) Pub. Date: May 14, 2026

(54) Charge Transport Device Enabled by Topological States for Room Temperature Applications

(71) Applicant: The Board of Trustees of the Leland Stanford Junior University, Stanford, CA (US)

(72) Inventors: Friedrich B. Prinz, Woodside, CA (US); Settasit Chaikasetsin, Santa Clara, CA (US); Tyler Trettel Howard, Stanford, CA (US); Daniel l. Custer, Stanford, CA (US); Xiting Zhang, Stanford, CA (US); Gwon Deok Han, Palo Alto, CA (US); Yonghyun Lim, Palo Alto, CA (US); Alexander Kaiser Boulton-McKeehan, Bellevue, WA (US)

(21) Appl. No.: 19/118,935

(22) PCT Filed: Oct. 30, 2023
(86) PCT No.: PCT/US2023/036264

§ 371 Date: Apr. 7, 2025

Related U.S. Application Data
(60) Provisional application No. 63/420,379, filed on Oct. 28, 2022.

(51) Int. Cl. H10N 60/30

(52) U.S. Cl. CPC H10N 60/30

(57) ABSTRACT

Anomalously large charge transport is provided using room temperature MIS (Metal-Insulator-Semiconductor) capacitive structures. Conductance can be 1 O× or more (often orders of magnitude more) than what would be expected from the classical properties of the structure. This anomalous behavior is attributed to topological states formed in the MIS structures under bias when there are both in-plane and out of plane components of the biasing electric field. One signature of this new physical effect is lateral supercurrents between the MIS structures. Another signature of this new physical effect is observation of quantum Hall effects at room temperature and in the absence of significant magnetic fields.

### FIELD OF THE INVENTION

This invention relates to charge storage and transport devices.

### BACKGROUND

Nonclassical electrical effects such as superconductivity, Quantum Hall effect etc. are well known in the art to require cryogenic temperatures, intense magnetic fields, or both. Although there have been various theoretical proposals of possible room temperature nonclassical electrical effects, there are few experimental demonstrations to date of such effects. Accordingly, it would be an advance in the art to provide room temperature nonclassical electrical effects.

### SUMMARY

We have found experimental evidence of nonclassical behavior of capacitive MIS (Metal/Insulator/Semiconductor) structures. In particular, room temperature charge storage, charge release and current transport in our experimental results can be far higher (i.e., orders of magnitude higher) than what would be expected from the classical capacitance of the MIS structure.

Without being bound by theory, it is presently believed that in these and similar geometries, certain electric and/or magnetic field distributions enable the transformation of conventional electronic charges with random phases into states of matter with a topological phase. The finite element simulation with Maxwell's equations reveals that the polarization of transient electric and/or magnetic fields induces regions of high electron densities that, in turn, might lead to topological surface states. A topological electronic phase is characterized by nontrivial topological invariants and represents a state of matter with unique physical properties. For example, the Maxwell equations, which determine the behavior of traditional charges together with associated electric and magnetic fields, are modified in the presence of topological phases. The occurrence of such phases is suggested by the density functional theory simulation leading to non-trivial topological invariants.

Such topological phases may lead to enhanced charge accumulation, enabling the creation of topological capacitors with higher releasable charge densities when compared to traditional capacitors. Electronic charges get stored and may be retrieved upon voltage reversal. Charges retrieved are substantially higher compared to traditional capacitors. The charge density retrieved from smaller devices is higher compared to the charge density retrieved from larger devices.

Topological phase differences in these capacitors may lead to the formation of supercurrents towards equilibrating the phase difference between anode and cathode. Such supercurrents can significantly exceed 1000 Amp/cm² without any observed sample damage. FEM (Finite Element Method) calculations show that traditional charge transport with observed supercurrent densities would lead to the instant melting of the sample. In contrast, the capacitors of this work can deliver high current density pulses without apparent damage. Moreover, present capacitors show higher current density pulses in smaller devices compared to current pulses from larger ones, contrary to traditional capacitive devices. Traditional capacitive currents scale with the area but not with one over the area, as observed here.

Accordingly, in the remainder of this description, “topological states” are defined phenomenologically such that any capacitive device having room temperature charge storage, charge release and/or current transport at least 10× what would be expected from the corresponding classical capacitance is regarded as having “topological states” that are responsible for these remarkable observations. We also regard observation of Quantum Hall phenomena at room temperature and in the absence of significant magnetic field as a sign that topological states are present.

Significant advantages are provided. Energy density and power density devices are limited in performance today. The architectures considered herein may enhance both metrics significantly. Josephson like transport is known to occur only at very low temperature. We may have observed super currents at room temperature. Some of our devices exhibit current densities of at least 1000 Amps per cm².

Earlier experimental work by our research group found anomalously high charge storage behavior in devices referred to as “all-electron batteries”. An exemplary reference for this work is U.S. patent application Ser. No. 12/798,102, filed on Mar. 29, 2010. However, the idea of forming topological electron states in room temperature semiconductors using in-plane and out-of-plane electrical bias of a low-dimensional electron gas was not considered in U.S. patent application Ser. No. 12/798,102.

### BRIEF DESCRIPTION OF THE DRAWINGS

FIGS. 1A-D schematically show non-classical MIS device operation in accordance with principles of the invention.

FIG. 2A-B show non-classical MIS devices configured to exhibit lateral supercurrent.

FIG. 3 is an exemplary I-V curve showing lateral supercurrent.

FIGS. 4A-B schematically show two options for lateral transport using non-classical MIS device operation.

FIGS. 5A-B show the effect of disrupting the non-classical MIS device operation on lateral current transport.

FIG. 6 shows disruption of non-classical MIS device operation with a voltage excursion.

FIGS. 7A-B show disruption of non-classical MIS device operation with a temperature excursion.

FIGS. 8A-D schematically show several options for controlling lateral supercurrent with applied perturbations.

FIG. 9 is a histogram of measured quantum Hall filling factors showing a dominant filling factor of ⅓.

FIG. 10 shows a measured impedance spectrum of a device in a state having a quantum Hall fill factor of 1.

### DETAILED DESCRIPTION

Section A describes general principles relating to embodiments of the invention. Section B describes several experimental examples.

### A) General Principles

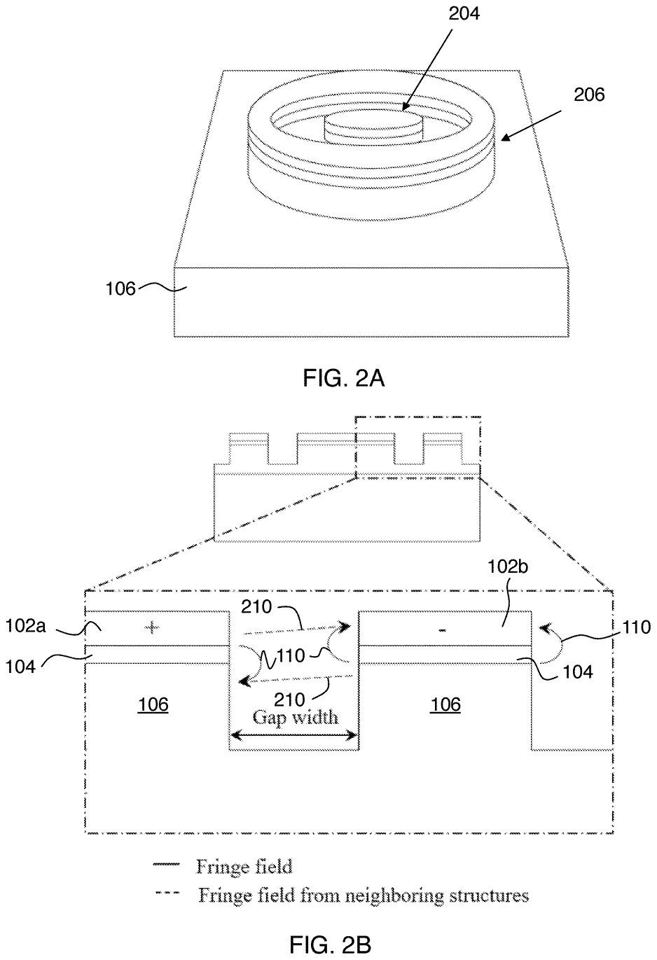

An exemplary embodiment of the invention is a method of providing lateral supercurrent transport between two MIS structures, where the method includes:
forming a first low-dimensional electron gas in a first MIS (metal-insulator-semiconductor) structure (e. g., 204 on FIG. 2A), where a first applied voltage to the first MIS structure results in first electric field components that are both parallel to the first low-dimensional electron gas and perpendicular to the first low-dimensional electron gas; and
forming a second-low dimensional electron gas in a second MIS structure (e.g., 206 on FIG. 2A), where a second applied voltage to the second MIS structure results in second electric field components that are both parallel to the second low-dimensional electron gas and perpendicular to the second low-dimensional electron gas; and
laterally coupling the first MIS structure to the second MIS structure (e.g. via fringing fields 210 on FIG. 2B). Here the first MIS structure has first topological states formed by injection of charge carriers, and the second MIS structure has second topological states formed by injection of charge carriers.

This method can further include cycling a lateral applied voltage until lateral transport between the first MIS structure and the second MIS structure show anomalously low resistance. Here we define “anomalously low resistance” as resistance 10× or more below what would be expected from conventional device physics.

Switching off anomalously low-resistance lateral transport can be done by applying a perturbation to the first MIS structure and/or to the second MIS structure sufficient to disrupt topological states. Suitable perturbations include: applied electrical bias, applied temperature rise, applied magnetic field, applied electromagnetic field, applied radio-frequency signal, and applied laser beam.

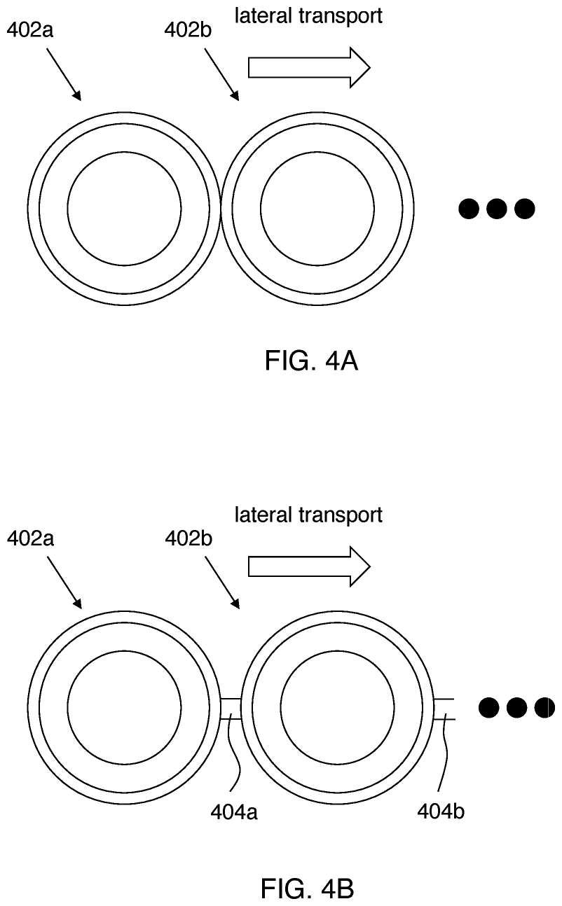

The first MIS structure can be laterally connected to the second MIS structure by direct lateral contact (e.g., as on FIG. 4A).

Alternatively, the first MIS structure can be laterally connected to the second MIS structure with a connection element (e.g., as on FIG. 4B). Here, switching off anomalously low-resistance lateral transport can be done by applying a perturbation to the connection element sufficient to disrupt topological states. Suitable perturbations include: applied electrical bias, applied temperature rise, applied magnetic field, applied electromagnetic field, applied radio-frequency signal, and applied laser beam.

The first topological states can be formed by voltage cycling the first MIS structure until vertical transport through the first MIS structure exhibits one or more features of quantum Hall conduction. Similarly, the second topological states can be formed by voltage cycling the second MIS structure until vertical transport through the second MIS structure exhibits one or more features of quantum Hall conduction.

More generally, another embodiment of the invention is a method of forming topological quantum states in a metal-insulator-semiconductor (MIS) structure, where the method includes:
voltage cycling the MIS structure until vertical transport through the MIS structure exhibits one or more features of quantum Hall conduction;
where the MIS structure includes a low-dimensional electron gas, and where an applied voltage to the MIS structure results in electric field components that are both parallel to the low-dimensional electron gas and perpendicular to the low-dimensional electron gas.

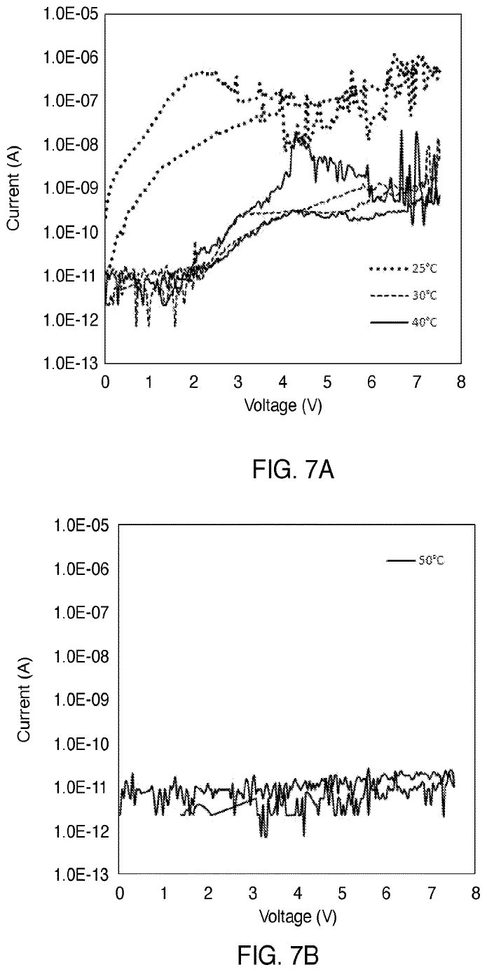

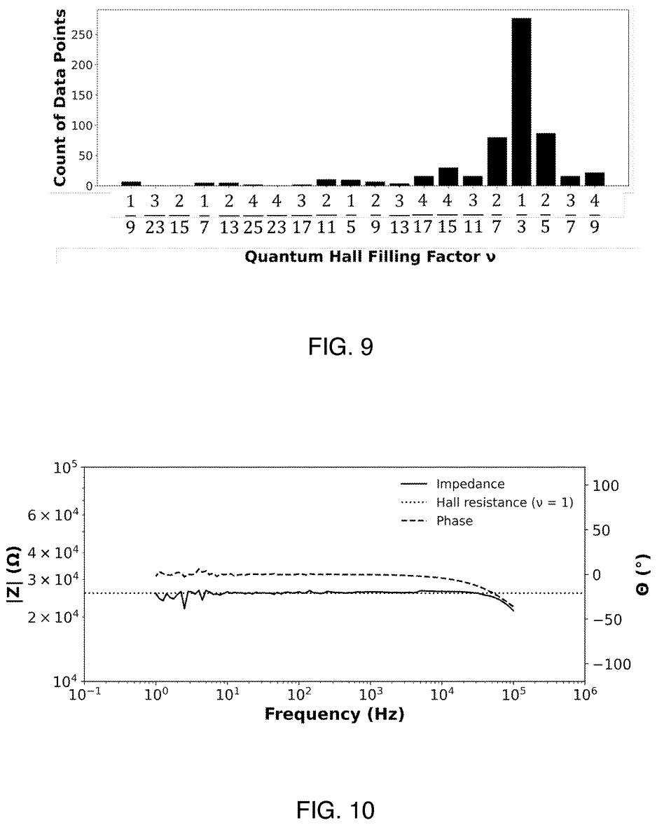

The MIS structure can be at a temperature of 25 C to 40 C, and the quantum Hall conduction is observed with no applied magnetic field. The superconducting current behavior is observed from 25 C to 40 C, as shown in FIG. 7A, which suggests that this anomalous quantum Hall conduction should also be present in a similar temperature range. Such room temperature quantum Hall conduction can be observed under DC bias or in AC bias in a frequency range from 1 Hz to 10 kHz (see FIGS. 9 and 10).

### B) Experimental Examples

### B1) Non-Classical MIS Devices

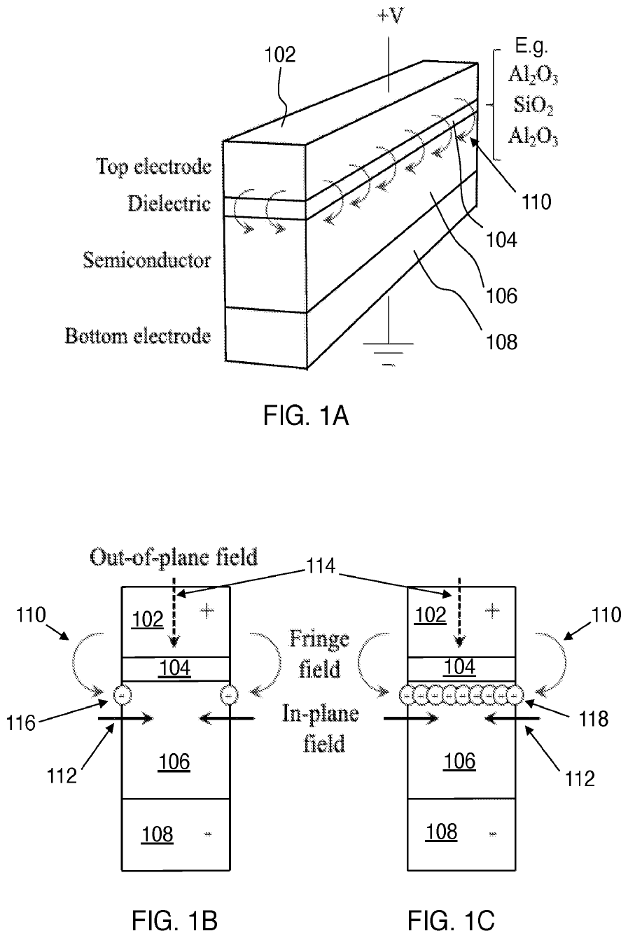

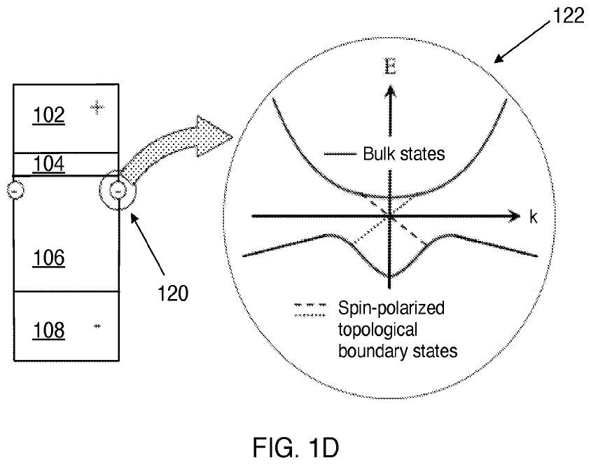

FIG. 1A shows an exemplary capacitive device including a high mobility semiconductor 106 and high breakdown strength dielectric 104 made into a slab shape and sandwiched between top electrode 102 and bottom electrode 108. For example, dielectric 104 can be a three-layer alumina/silica/alumina composite. FIGS. 1B-C are cross-sectional views of this device showing two components of applied electric fields: an out-of-plane component 114 and an in-plane component 112, which can both come from the fringe field 110, potentially inducing 1D electron surface states 116 as on FIG. 1B, or a 2D electron gas 118 as on FIG. 1C. Note that fringe fields are typically regarded as parasitics that would not be present in ideal devices, so this importance of fringe fields is an unexpected feature of this work. Standard cleanroom processing techniques can be used to fabricate the insulator, semiconductor and electrodes of the structures considered herein.

We have unexpectedly found that devices as in the example of FIGS. 1A-C can exhibit the characteristics of quantum charge storage and quantum charge transport at room temperature. The applied electric fields have both out-of-plane and in-plane components (114 and 112, respectively) inducing electronic boundary states, as shown in FIG. 1B and FIG. 1C. A portion of the injected electrons transforms into a topological phase in the form of 1D electron surface states or 2D electron gas states. The present device operates at room temperature and induces 1D or 2D electronic gases with applied electric fields only. The resulting unique states may be driven into topological states as indicated in FIG. 1D, or chargeless Majorana phase. More specifically, 120 on FIG. 1D is a schematic representation of a topological state, and 122 on FIG. 1D is a corresponding schematic energy-momentum energy band diagram. Typical geometrical parameters for such devices are as follows. Dielectric 104 can be a 100 nm thick three-layer alumina/silica/alumina composite. Semiconductor layer 106 preferably has a conductivity of at least 0.001 S/cm and is usually at least 150 nm thick. In the following examples, semiconductor 106 is p-doped silicon. Exemplary rectangular devices have widths from 0.2 μm to 250 μm and lengths from 1 μm to 250 μm. Exemplary circular devices have diameters from 2 μm to 100 μm.

An exemplary charging method is to connect the positive and negative electrodes of the source measure unit to the top and bottom electrodes of the device, respectively. Then, apply a linear voltage sweep starting at 0V, reaching a maximum voltage of 15 V, then sweeping back to 0V. Typical ramp rates for this sweeping are 10-500 mV/s. The current-voltage characteristics from the sweep will typically show a “peak current” at the “critical voltage” (i.e., we see the unusual feature that current does not increase monotonically with voltage). This critical voltage generally ranges from 3 to 8 V. These high current characteristics at critical voltages allow a supercurrent to pass through the sample. Current sweeps instead of voltage sweeps can also be performed.

### B2) Lateral Transport

In this work, we also consider lateral coupling of two devices as considered above. FIGS. 2A-B show an example. Here 204 is a central island and 206 is a surrounding ring, both of which, vertically, are devices as described above.

They are fabricated via lithography and etching process on a highly conductive p-type Si wafer 106 with conductivity at least 0.001 S/cm. FIG. 2B shows a detailed cross section view. Here electrodes 102a and 102b are both on the top, and the relevant fringing fields include fringing fields 110 from the island to the island and from the ring to the ring, and fringing fields 210 coupling the island and the ring. Details of the fringe fields depend mainly on the gap width or distance between structures. So far, the gap width between two devices in which we have experimentally seen non-classical coupling is from 1 μm to 450 μm. With short gap width (e.g., on the order of a um), the neighboring fringe field 210 will be important. With larger gap widths, there will be no effect from the neighboring fringe field 210. This is presently believed to be why repeat cycling is needed for larger gap widths.

For such a set of two structures that independently show high vertical current, such as ring 206 and island 204 on FIGS. 2A-B, the charge can be driven laterally by connecting one structure to the ground and while biasing the other structure (e.g., using top electrodes 102a and 102b). In this process, high current is observed in both structures, even extending over longer lateral distances with virtually no loss in current. If one structure does not show a high vertical current, this phenomenon is not observed.

More specifically, in these examples the setup for achieving lateral supercurrent starts with individually vertically biasing 204 and 206 to their respective critical voltages (which can be the same or different) using semiconductor 106 as the bottom electrode. Then, the electrical connection to semiconductor 106 is removed and the applied voltage is between the two top electrodes (e.g., 102a and 102b on FIG. 2B). There is thus a memory effect where devices 204 and 206 retain their non-classical behavior even when they are not being vertically biased. As seen below, lateral supercurrent is dependent on these devices being in their non-classical states, and when those states are disrupted (e.g., by a perturbation), the lateral supercurrent is also disrupted.

Each individual structure will self-induce a fringe field 110 relative to the charge being passed through it, as shown in FIG. 2B. However, the fringe fields will also interact with one another (210 on FIG. 2B), which helps induce the formation of topological electrons on each device. This current transfer is not immediate in all cases. For structures that are separated by longer distances, the in-plane charge transfer must be cycled a few times before the structure connected to the ground shows a near-lossless transfer in current from the first structure. The number of cycles required to establish current transfer is related to the distance between structures. For example, for a distance around 450 μm, at least 10 cycles of voltage cycling is needed.

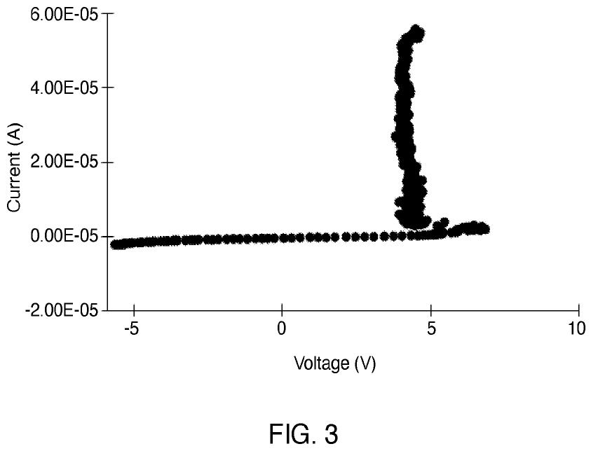

When this transfer, measured as current, is changed over time, the resulting I-V plot shows that the voltage will stay relatively stable as the current continues to increase, as shown on FIG. 3. This trend will continue, with voltage essentially oscillating in a small range, until the current reaches a maximum value. Above this value, the current will drop, and the voltage will maximize the limit value for the System Measurement Unit.

An exemplary charging method for the lateral current conduction is to apply a linear current sweep, such as a starting current of 0 A, a maximum current in a range of 40-800 μA and a ramp rate of 16 nA/s-16 μA/s. In cases where repeated current sweeps are performed, the sweeps used thus far have had a sawtooth waveform (i.e., sudden transition from the maximum current to no current to start the next iteration).

FIG. 3 shows an exemplary I-V plot from such a device. Within the range of 4.0 V to 4.8 V, the current continues to rise steadily. This eventually ceases once the current exceeds 60 μA.

By stringing or connecting such device in series, we may be able to accommodate the transport of superconductive current at room temperature. To utilize the supercurrent from surface states or from the topological surface states including the Majorana mode, we can connect multiple capacitors (e.g., 402a, 402b, . . . ) together at the ring, by touching or having dedicated bridges (e.g., 404a, 404b, . . . ) as depicted in FIG. 4A and FIG. 4B, respectively. With this connected capacitor geometry, we expect that the observed supercurrent in single capacitors can travel laterally in the in-plane direction through multiple connected capacitors. In this way, the in-plane transport will not be limited to the material conductivity, but rather the effectiveness of the promotion of the superconductive surface states.

It has to be noted that the bridges or the contact point of consecutive rings may vary. In particular, having one or more bridges, symmetric or asymmetric relative to the center line, including overlapping ring structures may be beneficial for the superconducting transfer mode.

### B3) Switching Off Lateral Transport via Perturbation

An applied perturbation can destabilize the protected states and end the coherency of the superconductive states. More specifically, the breakdown of the protected states means that one or both adjacent semiconductor devices lose their coherency of the superconductive state.

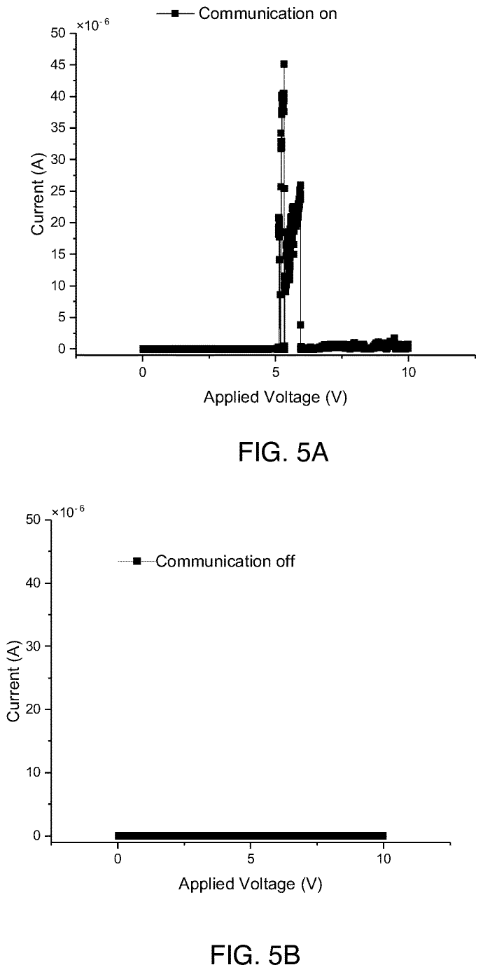

The device behavior with and without communication (i.e., before and after perturbation) is depicted in FIGS. 5A and 5B, respectively.

Suitable perturbation methods include but are not limited to the application of the externally generated electric field above the critical voltage, operation temperature control, magnetic field, radio frequency, and laser beam treatment. Two examples follow.

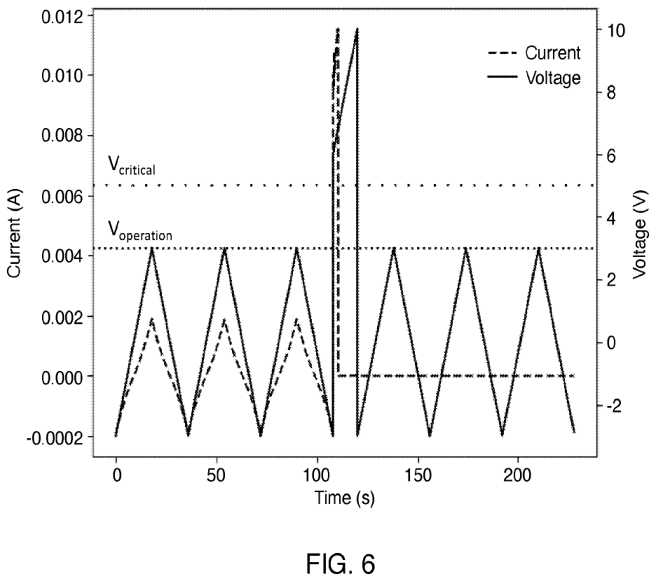

An application of a sudden ramp of voltage above the critical voltage (V_{critical}) can turn the device off, as shown in FIG. 6. An application of high-temperature heating can turn the device off, as shown in FIGS. 7A-B. FIG. 7A shows this specific device is in an on-state from 25° C. to 40° C., and FIG. 7B shows that a temperature of 50° C. turns the device into an off-state.

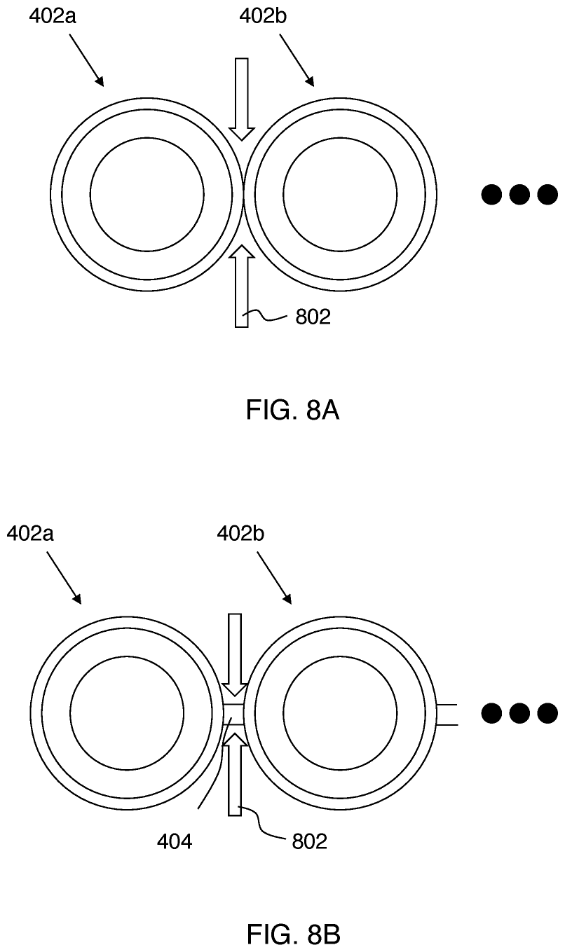

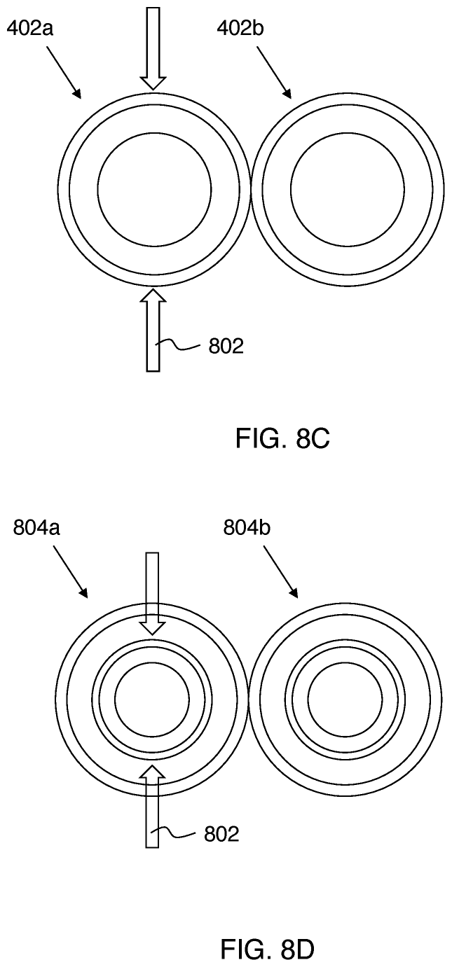

FIGS. 8A-D schematically show some examples of how such perturbations may be applied to laterally connected devices. In the example of FIG. 8A, perturbation 802 is applied at a contact point between devices 402a and 402b. In the example of FIG. 8B, perturbation 802 is applied to bridge 404 connecting devices 402a and 402b. In the example of FIG. 8C, perturbation 802 is applied directly to one of the devices (device 402a). In the example of FIG. 8D, the connected devices 804a and 804b are multi-ring structures, and perturbation 802 is applied to an inner ring of one of the devices.

### B4) Observation of Room Temperature Quantum Hall Effects

By applying linear DC voltage sweep to our Metal-Insulator-Semiconductor (MIS) device in the vertical direction, unconventionally high currents due to the formation and transport of topological chargeless edge/surface states at and through the conductor/insulator interfaces occurred at several critical voltages. When a constant DC bias in the vertical direction is applied at these critical voltages, the device exhibits integer and fractional quantum Hall resistance values. FIG. 9 shows resistance values centering around the fractional quantum Hall state with the quantum Hall filling factor of ν=⅓.

Another device of the same MIS structure showed a resistance value within 0.5% of the integer quantum Hall resistance corresponding to ν=1 when perturbed by an AC voltage centering around the critical voltage in the vertical direction, also due to the topological edge/surface states induced by previous linear voltage and current sweeps. This impedance value is stable at the ν=1 quantum Hall resistance level during the AC frequency sweep that ranges from 1 Hz to 10 kHz, as shown in FIG. 10.

An exemplary charging method to demonstrate such quantum Hall effects is the following:
1) Apply constant bias voltage at “critical voltage.” The critical voltages of the two devices shown in this observation are 7.7 V (FIG. 9) and 3.5 V (FIG. 10), respectively.
2) Then, observe the change in the current response to calculate device resistance (voltage divided by current). Alternatively, apply a small sinusoidal voltage (AC voltage) and sweep through different frequencies to obtain the impedance spectrum of the device. Here the root-mean-square value of AC voltage can be in a range from 50-200 mV with a frequency from 1 Hz to 10 KHz.

1. A method of providing lateral supercurrent transport between two MIS structures, the method comprising:
forming a first low-dimensional electron gas in a first MIS (metal-insulator-semiconductor) structure, wherein a first applied voltage to the first MIS structure results in first electric field components that are both parallel to the first low-dimensional electron gas and perpendicular to the first low-dimensional electron gas;
forming a second-low dimensional electron gas in a second MIS structure, wherein a second applied voltage to the second MIS structure results in second electric field components that are both parallel to the second low-dimensional electron gas and perpendicular to the second low-dimensional electron gas;
wherein the first MIS structure has first topological states formed by injection of charge carriers;
wherein the second MIS structure has second topological states formed by injection of charge carriers; and
laterally coupling the first MIS structure to the second MIS structure.

2. The method of claim 1, further comprising cycling a lateral applied voltage until lateral transport between the first MIS structure and the second MIS structure show anomalously low resistance.

3. The method of claim 2, further comprising switching off anomalously low-resistance lateral transport by applying a perturbation to the first MIS structure and/or to the second MIS structure sufficient to disrupt topological states.

4. The method of claim 3, wherein the perturbation is selected from the group consisting of: applied electrical bias, applied temperature rise, applied magnetic field, applied electromagnetic field, applied radio-frequency signal, and applied laser beam.

5. The method of claim 1, wherein the first MIS structure is laterally connected to the second MIS structure by direct lateral contact.

6. The method of claim 1, wherein the first MIS structure is laterally connected to the second MIS structure with a connection element.

7. The method of claim 6, further comprising switching off anomalously low-resistance lateral transport by applying a perturbation to the connection element sufficient to disrupt topological states.

8. The method of claim 7, wherein the perturbation is selected from the group consisting of: applied electrical bias, applied temperature rise, applied magnetic field, applied electromagnetic field, applied radio-frequency signal, and applied laser beam.

9. The method of claim 1, wherein the first topological states are formed by voltage cycling the first MIS structure until vertical transport through the first MIS structure exhibits one or more features of quantum Hall conduction.

10. The method of claim 1, wherein the second topological states are formed by voltage cycling the second MIS structure until vertical transport through the second MIS structure exhibits one or more features of quantum Hall conduction.

11. A method of forming topological quantum states in a metal-insulator-semiconductor (MIS) structure, the method comprising:
voltage cycling the MIS structure until vertical transport through the MIS structure exhibits one or more features of quantum Hall conduction;
wherein the MIS structure includes a low-dimensional electron gas, and wherein an applied voltage to the MIS structure results in electric field components that are both parallel to the low-dimensional electron gas and perpendicular to the low-dimensional electron gas.

12. The method of claim 11, wherein the MIS structure is at a temperature of 25 C to 40 C, and wherein the quantum Hall conduction is observed with no applied magnetic field.

13. The method of claim 11, wherein the quantum Hall conduction is observed under DC bias or in AC bias in a frequency range from 1 Hz to 10 kHz.
